(19) United States
(12) Patent Application Publication
(10) Pub. No.: US 2014/0230870 A1
(43) Pub. Date: Aug. 21, 2014

(54) Thermoelectric Conversion Elements

(71) Applicant: NGK INSULATORS, LTD., Aichi-prefecture (JP)

(72) Inventor: Jungo Kondo, Miyoshi-city (JP)

(73) Assignee: NGK INSULATORS, LTD., Aichi-prefecture (JP)

(21) Appl. No.: 14/183,597

(22) Filed: Feb. 19, 2014

(30) Foreign Application Priority Data
Feb. 21, 2013 (JP) 2013-032049

(51) Int. Cl. H01L 35/32; H01L 35/34

(52) U.S. Cl. CPC H01L 35/32; H01L 35/34
USPC 136/205; 438/54; 136/201

(57) ABSTRACT

It is provided a thermoelectric conversion element used at a high operation temperature of 500° C. or higher and including a laminate structure and electrodes. The laminate structure includes a plurality of p-type silicide substrates, and a plurality of n-type silicide substrates alternately laminated with each other, and adhesive layers each adhering the p-type and n-type silicide substrate adjacent to each other. The adhesive layer is made of a cured matter of an inorganic adhesive of a mixture of an inorganic binder and a filler. The electrodes are formed on the laminate structure and electrically connecting the p-type and n-type silicide substrates. The p-type and n-type silicide substrates have thicknesses of 0.5 mm or larger and 3.0 mm or smaller, the adhesive layer has a thickness of 0.5 mm or larger and 2.0 mm or smaller and has a thermal expansion coefficient of 7×10⁻⁶/° C. or larger and 16×10⁻⁶/° C. or smaller.

This application claims the benefit of Japanese Patent Application P2013-32049, filed on Feb. 21, 2013, the entirety of which is incorporated by reference.

### BACKGROUND OF THE INVENTION

1. Field of the Invention

The present invention relates to a thermoelectric conversion element for use at a high temperature, such as those utilizing exhaust heat of an automobile.

2. Related Art

In a field of energy conversion technique utilizing thermoelectric generation, it has been activated the development of products for the actual use and popularization, because environmental problems have attracted public attention. As to applications for automobiles, the ratio of utilization of the exhaust heat reaches roughly 30 percent and the remaining 70 percent of the exhaust heat is emitted without utilization. The application of a thermoelectric material is thus studied on the viewpoint of improvement of fuel consumption rate. However, an engine part of an automobile is operated at, for example, 600° C., so that it is required a thermoelectric conversion module which can be operated at a high temperature.

According to prior arts, it has been demanded a thermoelectric material having a high thermoelectric constant ZT for improving a thermoelectric efficiency, and it has been used a Bi—Te series semiconductor material. However, its properties are deteriorated at a high temperature of 500° C. or higher, it is required silicide, silicon-germanium, oxides, or half-Heusler series thermoelectric materials for a high temperature use.

It is described, in a non-patent document 1 (“Showa-densen Review”, Vol. 58, No. 1, 2008) to produce a thermoelectric conversion material of silicide or oxide series by powder metallurgy process. That is, rods of these materials are cut into many blocks to produce pieces of the thermoelectric elements. According to such process, however, mass-production is difficult to leave a problem of reducing the production cost.

On the other hand, as a method of improving generation efficiency of thermoelectric conversion elements, it is proposed to laminate substrates of an n-type thermoelectric material and substrates of a p-type thermoelectric material to provide a laminate structure, for improving an occupied ratio of space by the thermoelectric materials (Patent document 1 (Japanese Patent Application No. 2009-520460; U.S. Pat. No. 4,983,920B); Patent document 2 (Japanese Patent Publication No. 2011-046551A); Patent document 3 (Japanese Patent Publication No. 1999-121815A)). According to such thermoelectric conversion elements of the laminate structure, a plurality of the thermoelectric elements are integrated. It is thus possible to reduce the mounting cost of arranging the p-type and n-type thermoelectric elements as conventional thermoelectric elements and to provide a compact thermoelectric conversion module at a lower cost.
Non-patent document 1 (“Showa-densen Review”, Vol. 58, No. 1, 2008)
Patent document 1: Japanese Patent No. 4983920B
Patent document 2: Japanese Patent Publication No. 2011-046551A
Patent document 3: Japanese Patent Publication No. 1999-121815A
Patent document 4: Japanese Patent Publication No. 2003-258323A
Patent document 5: Japanese Patent Publication No. 2001-072500A
Patent Document 6: Japanese Patent No. 3882047B

### SUMMARY OF THE INVENTION

According to thermoelectric conversion elements, it is necessary to shield thermal conduction between its high and low temperature sides for maintaining a temperature difference between the high and low temperature sides. As the inventors studied to operate the thermoelectric element at a high temperature of 500° C. or higher adapted for use in exhaust gas of an automobile, however, it was proved that the reliability of the insulation and thermal conduction properties of its adhesive layer were deteriorated and the thermoelectric conversion efficiency was lowered for a long use time period.

An object of the present invention is, in a thermoelectric conversion element for use at a high temperature of 500° C. or higher, to reduce the deterioration of a generation efficiency of the thermoelectric conversion element over time.

The present invention provides a thermoelectric conversion element used at a high operation temperature of 500° C. or higher and including a laminate structure and electrodes. The laminate structure includes a plurality of p-type silicide substrates and a plurality of n-type silicide substrate alternately laminated with each other, and the laminate structure further includes adhesive layers each adhering the p-type silicide substrate and n-type silicide substrate adjacent to each other and comprising a cured matter of an inorganic adhesive of a mixture of an inorganic binder and a filler. The electrodes are formed on the laminate structure and electrically connecting the p-type silicide substrate and the n-type silicide substrate in series. The p-type silicide substrate and the n-type silicide substrate have thicknesses of 0.5 mm or larger and 3.0 m m or smaller, the adhesive layer has a thickness of 0.5 mm or larger and 2.0 mm or smaller and has a thermal expansion coefficient of 7×10⁻⁶/° C. or larger and 16×10⁻⁶/° C. or smaller.

The present invention further provides a method of producing a thermoelectric conversion element. The method comprises the steps of:

laminating p-type silicide substrates and n-type silicide substrates, providing an inorganic adhesive between said p-type silicide substrate and said n-type silicide substrate adjoining each other, the inorganic adhesive comprising a mixture of an inorganic binder and a filler, and curing the inorganic adhesive to form an adhesive layer comprising a cured matter to obtain a laminate structure; and

providing electrodes on the laminate structure for electrically connecting the p-type silicide substrate and the n-type silicide substrate in series.

The inventors studied the cause of the deterioration of generation efficiency as the thermoelectric conversion element is used for a long time at a high temperature, as described above. As a result, they reached the following discovery.

That is, in the case of the thermoelectric conversion element for use at a high temperature such as for an automobile and it is used a material having a thermoelectric figure of merit of about 1, for example, its Seebeck coefficient becomes 100 to 200 μV/K. In the case that the temperature difference reaches about 500° C., it is excited a voltage of 50 to 100 mV between both ends of the thermoelectric material. Therefore, in the case that the p-type and n-type thermoelectric materials are connected in series, the difference of potential between the both ends becomes 100 to 200 mV.

In the case of the thermoelectric conversion element of the laminate structure, its thermoelectric material is produced by green sheet or thin film process. It is thereby difficult to obtain a thick film as described in the patent document 2 (Japanese Patent Publication No. 2011-046551A) (it is described a thick film of up to 400 μm), and its thickness is between several tens to several hundreds μm. Further, it is similar in the adhesive layer, and the thickness of the adhesive layer is 50 μm for example in the Patent document 4 (Japanese Patent Publication No. 2003-258323A).

Therefore, according to the prior thermoelectric conversion element of the laminate structure, a gap between the p-type thermoelectric material and n-type thermoelectric material is normally 50 μm according to a printing method using green sheets (up to 400 μm according to the prior art), the electric field intensity in the gap becomes 2 to 4 V/mm. Although the electric field intensity is about 1/1000 of a dielectric breakdown of the adhesive layer, in the case that the electric field is applied at a high temperature of 500 to 600° C., for example, it was proved that the reliability of insulation and thermal conduction properties of the adhesive layer are deteriorated for a long time period and the thermoelectric conversion efficiency is lowered.

On the contrary, according to the inventive thermoelectric conversion element, it is possible to successfully provide a thermoelectric conversion element structure in which a high temperature difference can be maintained by an inorganic adhesive and the deterioration of the insulation and thermal conduction properties over time can be reduced.

### BRIEF DESCRIPTION OF THE DRAWINGS

FIG. 1(a) is a perspective view showing a p-type silicide substrate 1, FIG. 1(b) is a perspective view showing an n-type silicide substrate 2, and FIG. 1(c) is a broken perspective view showing a laminate structure of the p-type silicide substrates, n-type silicide substrates and inorganic adhesives 3.

FIG. 2 is a perspective view showing a laminate structure 4 obtained by curing the inorganic adhesives 3 shown in FIG. 1(c).

FIG. 3 is a perspective view showing a laminate structure 5 having a shape of a rectangle cut from the laminate structure 3 shown in FIG. 2.

FIG. 4 is a perspective view showing a thermoelectric conversion element 6 obtained by forming terminals 7A and 7B on side faces of the laminate structure 5 shown in FIG. 3.

FIG. 5 is a perspective view showing a thermoelectric conversion element 8 obtained by cutting the thermoelectric conversion element 6 shown in FIG. 4.

FIG. 6 is a perspective view showing a thermoelectric conversion module 15 obtained by mounting the thermoelectric conversion elements 8 of FIG. 5 on a common substrate 11.

### EMBODIMENTS OF THE INVENTION

The present invention will be further described below referring to the attached drawings.

(Thermoelectric Conversion Elements for Use at High Temperature)

The present invention provides a thermoelectric conversion element for high temperature use having a operation temperature of 500° C. or higher. This operation temperature may more preferably be 600° C. or higher. Further, although the upper limit of the operation temperature depends on the characteristics of its material, the operation temperature may be made 1200° C. or lower.

Such element may be used for recovering heat generated in an internal combustion engine of an automobile or recovering exhaust heat in industries (industrial furnaces, incinerators, small-scale thermal power stations or the like), and is expected as an important environmental technique.

(P-Type Silicide Substrate and n-Type Silicide Substrate)

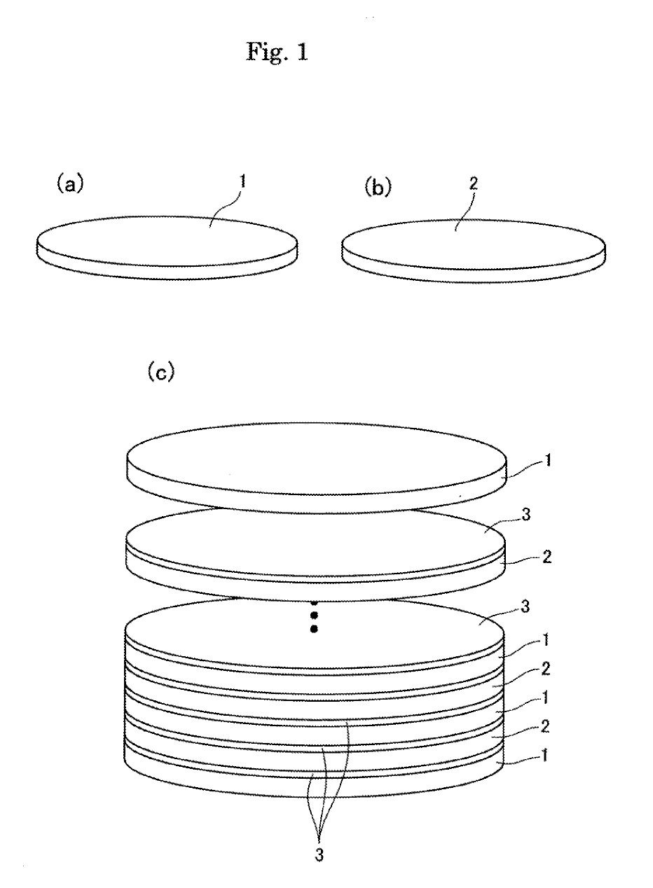

First, as shown in FIGS. 1(a) and 1(b), p-type silicide substrates 1 and n-type silicide substrates 2 are prepared.

Silicide means a compound composed of a metal and silicon. P-type silicide includes the followings.

Magnesium silicide, manganese silicide, iron silicide, neodymium silicide

Further, n-type silicide includes the followings.

Magnesium silicide, manganese silicide, iron silicide, neodymium silicide

Considering the generation of a stress due to a difference of thermal expansion coefficients, the p-type and n-type silicides may preferably be same.

For obtaining the p-type and n-type silicide substrates, preferably, a silicon wafer is used as a base material into which a metal is thermally diffused by vapor phase process. For example, as described in Patent document 5 (Japanese Patent Publication No. 2001-072500A), a silicon substrate and melt of an intermetallic compound held at a high temperature are reacted with each other to grow silicide crystal having a high melting point.

Alternatively, it is possible to synthesize silicide powder by powder metallurgy, to subject it to hot press sintering to produce a silicide sintered body, and to cut the silicide sintered body into plate-shaped bodies to obtain the substrates.

The p-type silicide substrates and n-type silicide substrates are alternately provided to constitute a thermoelectric conversion element. Here, the thickness of each of the p-type silicide substrate and n-type silicide substrate is made 0.5 mm or larger and 3 mm or smaller. It is possible to reduce the internal resistance and to improve an output current by making the thickness to 0.5 mm or larger. On the viewpoint, the thickness of each of the substrates may preferably be made 0.8 mm or larger. Further, it is possible to prevent the reduction of the output voltage per an unit volume by making the thickness of each of the p-type silicide substrate and the n-type silicide substrate to 3 mm or smaller. On the viewpoint, the thickness of the substrate may preferably be made 2 mm or smaller.

(Inorganic Adhesive and Adhesive Layer)

When the p-type and n-type silicide substrates are alternately laminated, an adhesive layer is provided between the substrates adjoining each other. Here, the adhesive layer is composed of a cured product of an inorganic adhesive of a mixture of an inorganic binder and a filler.

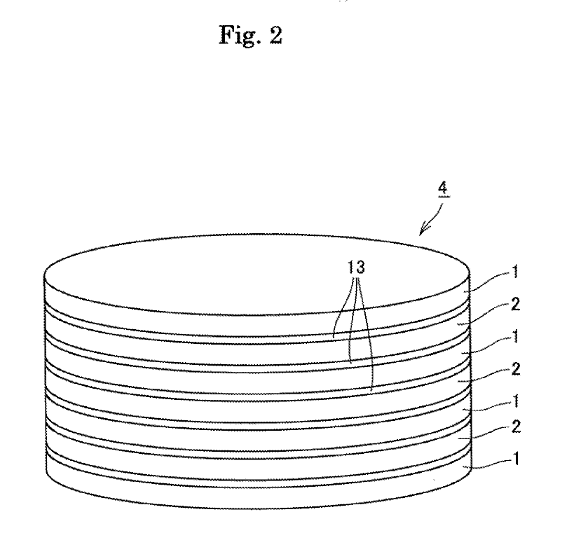

That is, as schematic shown in FIG. 1(c), the p-type silicide substrates 1 and n-type silicide substrates 2 are alternately laminated. At this time, an inorganic adhesive 3 is provided between the substrates 1 and 2 adjoining each other in the direction of the lamination. The inorganic adhesive 3 is then cured to form an adhesive layer 13 as shown in FIG. 2 so that a laminate structure 4 is obtained.

Here, as the inorganic binder constituting the inorganic adhesive, any material may be used as far as it is heat resistant after the curing at its operation temperature. It includes a silicate compound (sodium silicate, potassium silicate, lithium silicate or the like), a phosphate (phosphoric acid, aluminum phosphate, magnesium phosphate or the like), a low melting point glass, an inorganic compound having a high molecular weight (those including boron or phosphorous as the bone element), basic aluminum chloride, basic aluminum phosphate chloride, ethyl silicate, zirconium acetate and a metal (aluminum, calcium, sodium or the like) alkoxide.

The filler facilitates the evaporation of water content during the curing of the inorganic adhesive, prevents the foaming and reacts with the binder content to generate non-aqueous compound, so as to improve the water resistance, anti-corrosion property of the substrate against the binder, adhesive strength, heat resistance, electrical properties, anti-humidity and anti-drug property.

Such filler includes an oxide such as silica, alumina, zirconia, magnesia, calcia, mullite or the like, a nitride such as boron nitride, silicon nitride or the like, and a carbide such as silicon carbide and titanium carbide.

Further, by making the viscosity of the inorganic adhesive before the curing to 9 Pa·s or larger, the thickness of the applied film can be made larger and the thickness of the adhesive layer can be thereby made larger. On the viewpoint, the viscosity of the inorganic adhesive before the curing can preferably be made 20 Pa·s or larger and more preferably be made 30 Pa·s or larger, so that the thickness can be controlled uniformly.

Further, the inorganic adhesive before the curing contains the binder as its aqueous solution and does not contain an organic solvent. It is possible to adjust the viscosity by adjusting the water content. The adhesive is heated and cured to evaporate the water content in the binder to precipitate an inorganic polymer compound in the binder to provide the adhesion. The properties after the adhesion depend on the characteristics of the filler.

However, in the case that the binder is a metal alkoxide, the metal alkoxide is dispersed or dissolved in an organic solvent so that the viscosity can be adjusted. Such solvent includes an alcohol such as methanol, ethanol, butanol or the like.

The thickness of the adhesive layer 13 after the curing is made 0.5 mm or larger, so that the deterioration of the reliability of the adhesive layers in the gaps between the thermoelectric conversion materials to prevent the reduction of the output voltage over time. On the viewpoint, the thickness of the adhesive layer may more preferably be made 0.8 mm or larger.

Further, the thickness of the adhesive layer after the curing may preferably be 2 mm or smaller, so that the deterioration of the output voltage over time can be prevented.

The adhesive layer has a thermal expansion coefficient of 7×10⁻⁶/° C. to 16×10⁻⁶/° C., on the viewpoint that the thermal expansion coefficient is near to that of the silicide series thermoelectric conversion element.

Further, the curing of the inorganic adhesive may preferably be carried out at a temperature of 200° C. or higher and more at 200 to 300°, so that the cured product is stabilized at an operation temperature of 500° C. or higher.

(Cutting of Laminate Structure)

The laminate structure shown in FIG. 2 can be cut further in the direction perpendicular to each substrate, so that a plurality of laminate structures each having a smaller planar size can be formed. It is thus possible to improve the productivity of the thermoelectric conversion elements.

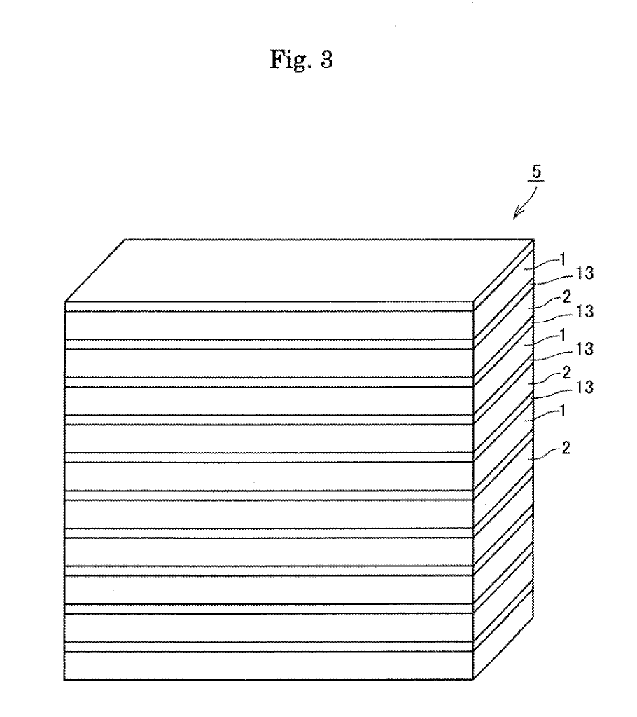

For example, the laminate structure 4 of FIG. 2 has a shape of a circular wafer in a plan view, for example. The laminate structure is cut in the direction perpendicular to each substrate 1 or 2, so that laminate structures 5 each having a shape of a rectangle, for example, can be obtained as shown in FIG. 3. In this case, each of the p-type silicide substrate and n-type silicide substrate has a shape of a rectangle in a plan view.

According the present embodiment, on the viewpoint of lowering the internal resistance and increasing the current, the length of the long side of the rectangular shape of each of the p-type and n-type silicide substrates may preferably be 10 mm or larger and more preferably be 15 mm or larger. Further, on the viewpoint of preventing cracks and fractures of the substrates, the length of the long side of the rectangular shape of each of the p-type and n-type silicide substrates may preferably be 40 mm or smaller.

According to a preferred embodiment, an oxide film is formed on at least one of main faces of the n-type and p-type silicide substrates. The oxide film may be formed on both of the main faces of the n-type and p-type silicide substrates. The oxide film may preferably be made of a material having a lower thermal conduction and a larger electrical resistance than those of the silicide substrate. The thermal expansion coefficient of the oxide film may preferably be 7×10⁻⁶/° C. or larger and 16×10⁻⁶/° C. or smaller. Such oxide film may be formed by vapor phase deposition, sputtering, sol-gel method, hydrothermal synthesis or the like.

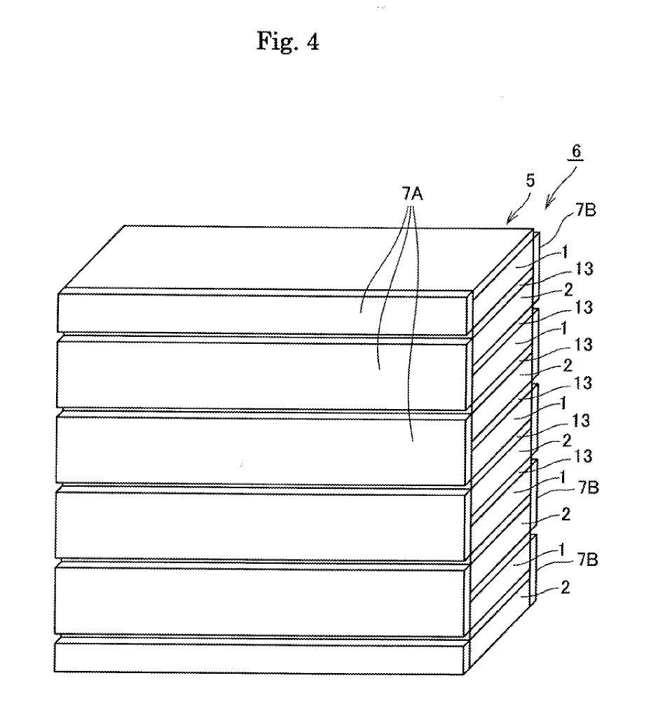

Then, as shown in FIG. 4, electrodes 7A and 7B are formed on side faces of the laminate structure, so that the p-type and n-type silicide substrates adjoining each other in the direction of the lamination are electrically connected through the electrode.

The material, shape and production method of such electrodes are not particularly limited. For example, electroplating, electroless plating, combination of electroplating and electroless plating are listed. Further, the electrode may be formed by sintering conductive paste. Further, materials of the electrodes include the followings.

Gold, silver, copper, platinum, nickel, carbon, or an alloy containing the metal.

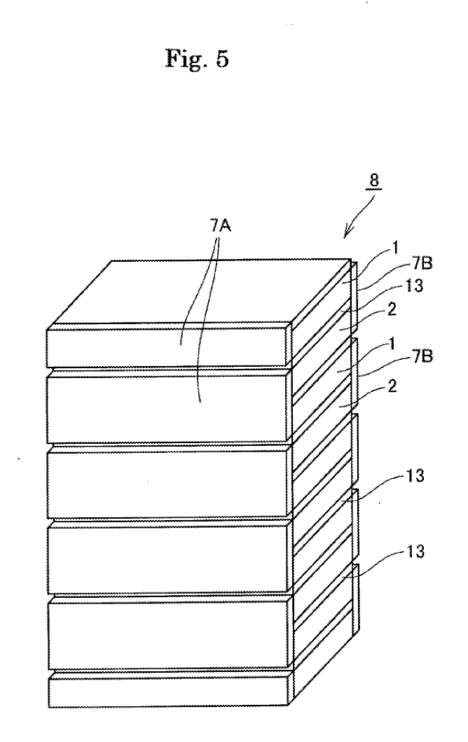

Further, as shown in FIG. 4, after the electrodes are provided on the laminate structure to form the thermoelectric conversion element 6, the thermoelectric conversion element may be further cut into a plurality of thermoelectric conversion elements. For example, the element 6 shown in FIG. 4 may be cut into two or more thermoelectric conversion elements 8 shown in FIG. 5.

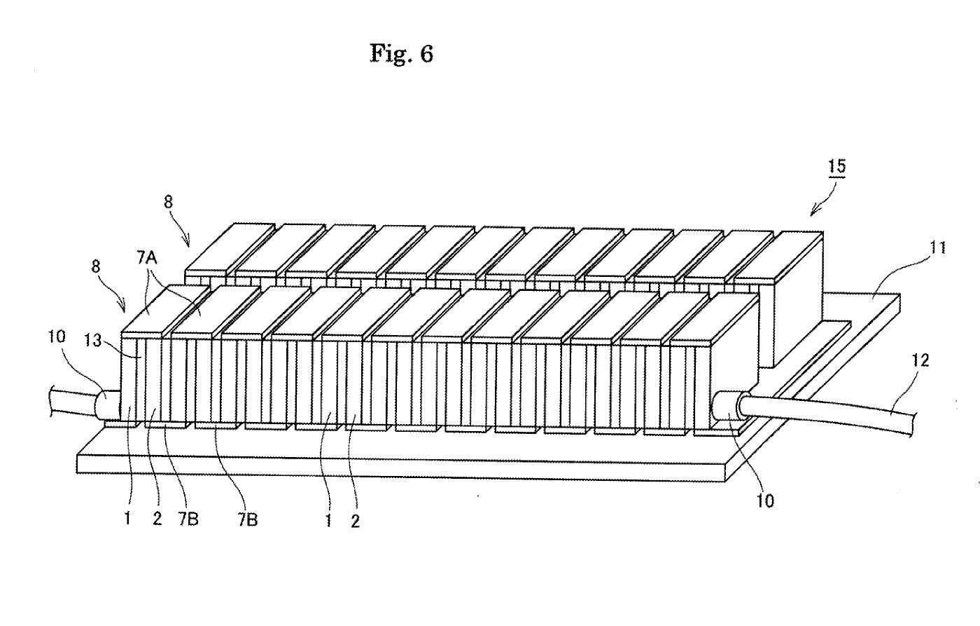

Further, a plurality of the thermoelectric conversion elements may be mounted on a common mounting substrate and connected in series or in parallel to constitute a thermoelectric conversion module 16. For example, according to the example of FIG. 6, two thermoelectric conversion elements 8 are mounted and fixed on the common mounting substrate 11. According to the example, the electrode 7B is provided on the side of the substrate 11 and the electrode 7A is provided on the upper side of the thermoelectric conversion element 8. The electrode 7B is connected to a pair of outer terminals 10, and the outer terminals 10 are connected to the outside through electric lines 12. The two thermoelectric conversion elements may be connected in series or in parallel.

### EXAMPLES

(Production Process of Thermoelectric Conversion Module)

A thermoelectric conversion module was produced according to the procedure described referring to FIGS. 1 to 5.

Specifically, it was prepared a silicon wafer of 3 inches having a thickness of 1 mm and an orientation of (111), and the silicon wafer was converted to magnesium silicide. The synthesis of magnesium silicide was performed according to the method described in Patent document 6 (Japanese Patent No. 3882047B). Specifically, the silicon wafer and magnesium metal were weighed in a molar ratio of Si:Mg=1:2, and contained in a magnetic crucible with magnesium chloride. Thereafter, the crucible was placed in an electric furnace and then subjected to heat treatment for 20 hours at 900° C. to obtain magnesium silicide. Here, Cu was vacuum deposited as a dopant on the obtained p-type silicide substrate. The n-type silicide substrate was not doped.

The thus obtained p-type and n-type magnesium silicide wafers 1 and 2 were alternately laminated through a ceramic series adhesive (SUMICERAM) 3 to obtain a laminated body (FIG. 1(c)). It was used “SUMICERAM” supplied by SUMICA CHEMTEX Co. Ltd. and having a viscosity of 50 Pa·s and a thermal expansion coefficient of 8 ppm/° C. For example, in the case that the silicide wafer had a thickness of 1 mm, the adhesive was applied by a dispenser so that the thickness after the adhesion becomes uniform and 0.5 mm to obtain a laminated body having a height of 25 mm.

Besides, the inorganic adhesive contained a silicate compound as the inorganic binder and silica and alumina as the filler.

The adhesive was then cured. That is, it was preliminarily cured at 100° C. for about one hour and then cured at 300° C. for 1 hour. After the curing, the laminate structure 4 was cut into the thermoelectric conversion elements 5 (sub modules) each having a width of 5 mm and a length of 19 mm by slicing. Next, the electrodes 7A and 7B were formed as shown in FIG. 4 so that the p-type and n-type thermoelectric conversion elements on the side faces are connected in series. Further, the thermoelectric conversion elements 8 were provided on the common mounting substrate 11, and the thermoelectric conversion elements are connected in series to produce a thermoelectric conversion module 15 having total sizes of 25 mm×40 mm×5 mm.

An output of thermoelectricity was measured under the condition of 500° C. at the high temperature side for the thus obtained thermoelectric conversion module to calculate the thermoelectric conversion efficiency. The thermoelectric conversion efficiency is defined as a ratio of an input calorific value and an electrical output power. For example, in the case that the thickness of the silicide substrate described later was 1 mm, the output of the thermoelectricity was 2.5 W/cm² and the thermoelectric conversion efficiency was 11 percent.

### Experiment 1

### Dependency on Thickness of Silicide Substrate

The thermoelectric conversion element was produced as described above. However, the thicknesses of the silicide substrates were made 0.25 mm to 3.5 mm, and the thickness of the adhesive layer was made 0.5 mm. 10 layers of the p-type silicide substrates and 10 layers or n-type silicide substrates were laminated. Thereafter, the thus obtained laminate structure was cut into chips of the laminate structures each having a width of 5 mm and length of 19 mm, and the laminate structures were connected in series through the electrodes 7A and 7B to produce the thermoelectric conversion element having a length of 40 mm and a thickness of 5 mm. The thermoelectromotive force was measured under the condition of 650° C. at the high temperature side. Table 1 shows results of the measurement of the thermoelectromotive forces with respect to the thicknesses of the substrates.

TABLE 1

| Thickness of | Thickness of | Output |
|---|---|---|
| silicide substrate (mm) | stack (mm) | voltage (V) |
| 0.25 | 7 | 0.8 |
| 0.4 | 13 | 1.7 |
| 0.5 | 15 | 2 |
| 1.0 | 25 | 2 |
| 1.5 | 35 | 2.1 |
| 2.0 | 45 | 2.1 |
| 2.5 | 55 | 2.1 |
| 3.0 | 65 | 2.2 |
| 3.1 | 67 | 2.2 |
| 3.5 | 75 | 2.2 |

Besides, “thickness of stack” in table 1 corresponds with the width of the stack after assembling the module.

It was possible to make the temperature difference to 500° C. or larger and to improve the output voltage, by making the thickness of the silicide substrate to 0.5 mm or larger.

### Example 2

### Dependency on Thickness of Adhesive Layer

The thermoelectric conversion element was produced as the Experiment 1. However, the thicknesses of the adhesive layers were made 0.1 mm to 3 mm, and the thickness of the silicide substrate was made 1.0 mm. Table 2 shows results of the measurement of the thermoelectromotive forces with respect to the thicknesses of the adhesive layers.

TABLE 2

| Thickness of | Thickness of | Output |
|---|---|---|
| adhesive layer (mm) | stack (mm) | voltage (V) |
| 0.1 | 21 | 0.8 |
| 0.4 | 24 | 1.7 |
| 0.5 | 25 | 2.1 |
| 1.0 | 40 | 2.1 |
| 1.5 | 50 | 2.1 |
| 2.0 | 60 | 2.1 |
| 2.1 | 70 | 2.1 |
| 2.5 | 80 | 2.1 |

It was possible to make the temperature difference to 500° C. or larger and to obtain a sufficiently high output power, by making the thickness of the adhesive layer to 0.5 mm or larger.

### Experiment 3

### Long-Term Reliability

Endurance test was performed for each of the thermoelectric conversion module produced in the Experiments 1 and 2. Specifically, operation test was continued at an ambient temperature of 550° C. for 300 hours to measure the change of the thermoelectromotive force. Tables 3 and 4 show the results.

TABLE 3

| Thickness of | Output voltage (V) | | Number of samples |
|---|---|---|---|
| silicide substrate (mm) | initial | After 500 Hours | (counts) |
| 0.25 | 0.8 | 0.8 | 10 |
| 0.4 | 1.7 | 1.7 | 10 |
| 0.5 | 2 | 2 | 10 |
| 1.0 | 2 | 2 | 10 |
| 1.5 | 2.1 | 2.1 | 10 |
| 2.0 | 2.1 | 2.1 | 10 |
| 2.5 | 2.1 | 2.1 | 10 |
| 3.0 | 2.2 | 2.2 | 10 |
| 3.1 | 2.2 | 1.8 | 10 |
| 3.5 | 2.2 | 1.5 | 10 |

TABLE 4

| Thickness of | Output voltage (V) | | Number of samples |
|---|---|---|---|
| Adhesive layer (mm) | Initial | After 500 Hours | (counts) |
| 0.1 | 0.8 | 0.8 | 10 |
| 0.4 | 1.7 | 1.7 | 10 |
| 0.5 | 2.1 | 2.1 | 10 |
| 1.0 | 2.1 | 2.1 | 10 |
| 1.5 | 2.1 | 2.1 | 10 |
| 2.0 | 2.1 | 2.1 | 10 |
| 2.1 | 2.1 | 1.8 | 10 |
| 2.5 | 2.1 | 1.6 | 10 |

That is, it was possible to maintain the output voltage after 500 hours high as well as the initial value, by making the thickness of the silicide substrate to 0.5 mm to 3.0 mm and by making the thickness of the adhesive layer to 0.5 to 2.0 mm. This means that the deterioration of the reliability of the insulation and thermal conduction properties over time can be prevented and the thermoelectric conversion efficiency can be maintained high, according to the present invention.

1. A thermoelectric conversion element for use at a high operation temperature of 500° C. or higher, said thermoelectric conversion element comprising a laminate structure and electrodes;
said laminate structure comprising a plurality of p-type silicide substrates and a plurality of n-type silicide substrates alternately laminated with each other, and said laminate structure further comprising adhesive layers each adhering said p-type silicide substrate and n-type silicide substrate adjacent to each other and comprising a cured matter of an inorganic adhesive comprising a mixture of an inorganic binder and a filler;
each of said electrode being formed on said laminate structure and electrically connecting said p-type silicide substrate and said n-type silicide substrate in series;
wherein said p-type silicide substrate and said n-type silicide substrate have thicknesses of 0.5 mm or larger and 3.0 mm or smaller;
wherein said adhesive layer has a thickness of 0.5 mm or larger and 2.0 mm or smaller; and
wherein said adhesive layer has a thermal expansion coefficient of 7×10⁻⁶/° C. or larger and 16×10⁻⁶/° C. or smaller.

2. The element of claim 1, wherein each of said p-type silicide substrate and said n-type silicide substrate has a shape of a rectangle whose long side has a length of 15 mm or larger.

3. The element of claim 1, wherein said inorganic adhesive before curing has a viscosity of 20 Pa·s or larger.

4. The element of claim 1, further comprising an oxide film formed on a main face of at least one of said n-type silicide substrate and said p-type silicide substrate.

5. A thermoelectric conversion module comprising a plurality of said thermoelectric conversion elements of claim 1 electrically connected with each other.

6. A method of producing a thermoelectric conversion element, said method comprising the steps of:
laminating p-type silicide substrates and n-type silicide substrates, providing a inorganic adhesive between said p-type silicide substrate and said n-type silicide substrate adjoining each other, said inorganic adhesive comprising a mixture of an inorganic binder and a filler, and curing said inorganic adhesive to form a adhesive layer comprising a cured matter to obtain a laminate structure; and
providing electrodes on said laminate structure for electrically connecting said p-type silicide substrate and said n-type silicide substrate in series.

7. The method of claim 6, wherein each of said p-type silicide substrate and said n-type silicide substrate has a shape of a rectangle whose long side has a length of 15 mm or larger.

8. The method of claim 6, wherein said inorganic adhesive before curing has a viscosity of 20 Pa·s or larger.

9. The method of claim 6, further comprising the step of forming an oxide film on a main face of at least one of said n-type silicide substrate and said p-type silicide substrate.
